(19) United States
(12) Patent Application Publication
(10) Pub. No.: US 2019/0392879 A1
(43) Pub. Date: Dec. 26, 2019

(54) MAGNETIC MEMORY ELEMENT HAVING MgO ISOLATION LAYER

(71) Applicant: Spin Memory, Inc., Fremont, CA (US)

(72) Inventors: Jorge Vasquez, San Jose, CA (US); Bartlomiej Adam Kardasz, Pleasanton, CA (US)

(21) Appl. No.: 16/019,429

(22) Filed: Jun. 26, 2018

(51) Int. Cl. G11C 11/16; H01L 43/12; H01L 43/02; H01L 43/08; H01L 43/10

(52) U.S. Cl. CPC G11C 11/161; H01L 43/12; H01L 43/10; H01L 43/08; H01L 43/02

(57) ABSTRACT

A magnetic memory element array having a memory element structure that is robust against the affects of high temperature annealing. The memory element array includes a magnetic memory element pillar having a barrier layer (e.g. MgO). A first isolation layer is formed at the side of the memory element pillar, the first isolation layer being a material that is substantially the same as the barrier layer of the magnetic memory element pillar. A second isolation layer such as SiOx is formed such that the first isolation layer separates the second isolation layer from the magnetic memory element pillar. The presence of the first isolation layer advantageously prevents Si migration into the barrier layer during high temperature annealing and advantageously prevents the formation of nano-crystal filaments causing current shunts which would degrade performance of the magnetic memory element pillar.

### FIELD OF THE INVENTION

The present invention relates to magnetic random access memory (MRAM) and more particularly to a magnetic memory element having a MgO isolation layer located at the side of the memory element to improve robustness to high temperature processing.

### BACKGROUND

Magnetic Random Access Memory (MRAM) is a non-volatile data memory technology that stores data using magnetoresistive cells such as Magnetoresistive Tunnel Junction (MTJ) cells. At their most basic level, such MTJ elements include first and second magnetic layers that are separated by a thin, non-magnetic layer such as a tunnel barrier layer, which can be constructed of a material such as Mg—O. The first magnetic layer, which can be referred to as a reference layer, has a magnetization that is fixed in a direction that is perpendicular to that plane of the layer. The second magnetic layer, which can be referred to as a magnetic free layer, has a magnetization that is free to move so that it can be oriented in either of two directions that are both generally perpendicular to the plane of the magnetic free layer. Therefore, the magnetization of the free layer can be either parallel with the magnetization of the reference layer or anti-parallel with the direction of the reference layer (i.e. opposite to the direction of the reference layer).

The electrical resistance through the MTJ element in a direction perpendicular to the planes of the layers changes with the relative orientations of the magnetizations of the magnetic reference layer and magnetic free layer. When the magnetization of the magnetic free layer is oriented in the same direction as the magnetization of the magnetic reference layer, the electrical resistance through the MTJ element is at its lowest electrical resistance state. Conversely, when the magnetization of the magnetic free layer is in a direction that is opposite to that of the magnetic reference layer, the electrical resistance across the MTJ element is at its highest electrical resistance state.

The switching of the MTJ element between high and low resistance states results from electron spin transfer. An electron has a spin orientation. Generally, electrons flowing through a conductive material have random spin orientations with no net spin orientation. However, when electrons flow through a magnetized layer, the spin orientations of the electrons become aligned so that there is a net aligned orientation of electrons flowing through the magnetic layer, and the orientation of this alignment is dependent on the orientation of the magnetization of the magnetic layer through which they travel. When the orientations of the magnetizations of the free and reference layer are oriented in the same direction, the majority spin of the electrons in the free layer are is in the same direction as the orientation of the majority spin of the electrons in the reference layer. Because these electron spins are in generally the same direction, the electrons can pass relatively easily through the tunnel barrier layer. However, if the orientations of the magnetizations of the free and reference layers are opposite to one another, the spin of majority electrons in the free layer will be generally opposite to the majority spin of electrons in the reference layer. In this case, electrons cannot easily pass through the barrier layer, resulting in a higher electrical resistance through the MTJ stack.

Because the MTJ element can be switched between low and high electrical resistance states, it can be used as a memory element to store a bit of data. For example, the low resistance state can be read as an on or “1”, whereas the high resistance state can be read as a “0”. In addition, because the magnetic orientation of the magnetic free layer remains in its switched orientation without any electrical power to the element, it provides a robust, non-volatile data memory bit.

To write a bit of data to the MTJ cell, the magnetic orientation of the magnetic free layer can be switched from a first direction to a second direction that is 180 degrees from the first direction. This can be accomplished, for example, by applying a current through the MTJ element in a direction that is perpendicular to the planes of the layers of the MTJ element. An electrical current applied in one direction will switch the magnetization of the free layer to a first orientation, whereas switching the direction of the current and such that it is applied in a second direction will switch the magnetization of the free layer to a second, opposite orientation. Once the magnetization of the free layer has been switched by the current, the state of the MTJ element can be read by reading a voltage across the MTJ element, thereby determining whether the MTJ element is in a “1” or “0” bit state. Advantageously, once the switching electrical current has been removed, the magnetic state of the free layer will remain in the switched orientation until such time as another electrical current is applied to again switch the MTJ element. Therefore, the recorded date bit is non-volatile in that it remains intact in the absence of any electrical power.

### SUMMARY

The present invention provides a magnetic memory device that includes a magnetic memory element having a side and having a barrier layer. The magnetic memory device further includes a first isolation layer formed of a material that is substantially the same as the material of the barrier layer, and a second isolation layer arranged such that the first isolation layer separates the second isolation layer from the magnetic memory element.

The barrier layer and the first isolation layer can be constructed of magnesium oxide, whereas the second isolation layer can be formed of a material such as silicon oxide, which provides good dielectric properties, good hardness and resistance to corrosion and also has good properties for chemical mechanical polishing. A third isolation layer, which can be constructed of a material such as silicon nitride can be provided over the second insulation layer and can serve as a chemical mechanical polishing (CMP) stop layer to facilitate manufacture of the device.

In a magnetic memory device, magnetic memory elements are connected with circuitry such as CMOS circuitry that requires high temperature treatment to be performed after formation of the magnetic memory element. This high temperature treatment can include treatment at temperatures of around 400 degrees C. for extended periods of time. This high temperature treatment can cause Si diffusion into the barrier layer which greatly degrades spin tunneling properties and decreases performance. In addition, the high temperature treatment can cause the formation of crystals at the outer edges of the barrier layer which can lead to current shunting and reduced electrical resistance of the memory element.

The presence of the first isolation layer advantageously prevents Si from migrating from the other isolation layer or layer and diffusing into the barrier layer. The first isolation layer also advantageously prevents the problematic formation of crystals at the outer edges of the barrier layer which would act as current shunts and greatly degrade performance of the device.

As discussed, the first isolation layer can be constructed of substantially the same material as the barrier layer. For example, if the barrier layer is constructed of magnesium oxide, the first isolation layer can be constructed of magnesium oxide having an oxygen content that is within plus or minus five atomic percent of that of the barrier layer.

These and other features and advantages of the invention will be apparent upon reading of the following detailed description of the embodiments taken in conjunction with the figures in which like reference numeral indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic, cross sectional view of a perpendicular magnetic tunnel junction (pMTJ) element, such as might be used in an embodiment of the invention;

FIG. 2 is a schematic cross-sectional view of a magnetic memory element according to an embodiment;

FIG. 3 is a schematic cross-sectional view of a magnetic memory element according to an alternate embodiment;

FIGS. 4-9 are cross-sectional schematic views of a magnetic memory element in various intermediate stages of manufacture, in order to illustrate a method of manufacturing a magnetic memory element according to an embodiment of the invention; and

FIGS. 10-16 are cross-sectional schematic views of a magnetic memory element in various s intermediate stages of manufacture in order to illustrate a method of manufacturing a magnetic memory element according to an alternate embodiment of the invention.

### DETAILED DESCRIPTION

The following description is of the best embodiments presently contemplated for carrying out this invention. This description is made for the purpose of illustrating the general principles of this invention and is not meant to limit the inventive concepts claimed herein.

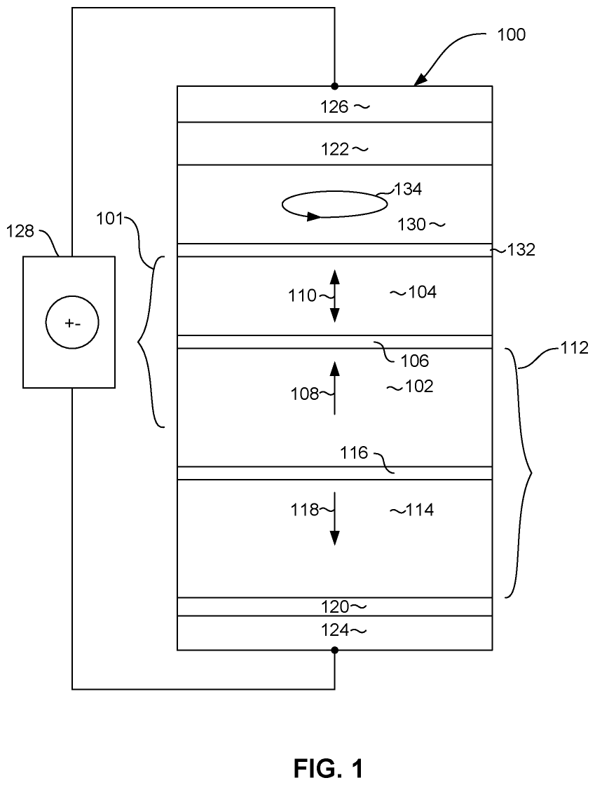

Referring now to FIG. 1, a magnetic memory element 100 can be in the form a of a perpendicular magnetic tunnel junction (pMTJ) memory element. The magnetic memory element can include an MTJ 101 that can include a magnetic reference layer 102, a magnetic free layer 104 and a thin, non-magnetic, electrically insulating magnetic barrier layer 106 located between the magnetic reference layer 102, and magnetic free layer 104. The barrier layer 106 can be an oxide such as MgO. The magnetic reference layer has a magnetization 108 that is fixed in a direction that is preferably perpendicular to the plane of the layers as indicated by arrow 108. The magnetic free layer has a magnetization 110 that can be in either of two directions perpendicular to the plane of the layer 104. While the magnetization 110 of the free layer remains in either of two directions perpendicular to the plane of the layer 104 in a quiescent state, it can be moved between these two directions as will be described in greater detail herein below. When the magnetization 110 of the magnetic free layer 104 is in the same direction as the magnetization 108 of the reference layer 102, the electrical resistance across the layers 102, 106, 104 is at a low resistance state. Conversely, when the magnetization 110 of the free layer 104 is opposite to the magnetization 108 of the reference layer 102, the electrical resistance across the layers 102, 106, 104 is in a high resistance state.

The magnetic reference layer 102 can be part of an anti-parallel magnetic pinning structure 112 that can include a magnetic keeper layer 114, and a non-magnetic, antiparallel coupling layer 116 located between the keeper layer 114 and reference layer 102. The antiparallel coupling layer 116 can be a material such as Ru and can be constructed to have a thickness such that it will ferromagnetically antiparallel couple the layers 114, 102. The antiparallel coupling between the layers 114, 102 pins the magnetization 108 of the reference layer 102 in a direction opposite to the direction of magnetization 118 of the keeper layer 114.

A seed layer 120 may be provided near the bottom of the memory element 100 to initiate a desired crystalline structure in the above deposited layers. A capping layer 122 may be provided near the top of the memory element 100 to protect the underlying layers during manufacture, such as during high temperature annealing and from exposure to ambient atmosphere. Also, electrodes 124, 126 may be provided at the top and bottom of the memory element 100. The electrodes 124, 126 may be constructed of a non-magnetic, electrically conductive material such as Ta, W, Cu and Al can provide electrical connection with circuitry 128 that can include a current source and can further include circuitry for reading an electrical resistance across the memory element 100.

The magnetic free layer 104 has a perpendicular magnetic anisotropy that causes the magnetization 110 of the free layer 104 to remain stable in one of two directions perpendicular to the plane of the free layer 104. In a write mode, the orientation of the magnetization 110 of the free layer 104 can be switched between these two directions by applying an electrical current through the memory element 100 from the circuitry 128. A current in one direction will cause the memory element to flip to a first orientation, and a current in an opposite direction will cause the magnetization to flip to a second, opposite direction. For example, if the magnetization 110 is initially oriented in a downward direction in FIG. 1, applying a current in a downward direction through the element 100 will cause electrons to flow in an opposite direction upward through the element 100. The electrons travelling through the reference layer will become spin polarized as a result of the magnetization 108 of the reference layer 102. These spin polarized electrons cause a spin torque on the magnetization 110 of the free layer 104, which causes the magnetization to flip directions.

On the other hand, if the magnetization 110 of the free layer 104 is initially in an upward direction in FIG. 1, applying an electrical current through the element 100 in an upward direction will cause electrons to flow in an opposite direction, downward through the element 100. However, because the magnetization 110 of the free layer 104 is opposite to the magnetization 108 of the reference layer 102, the electrons with an opposite spin will not be able to pass through the barrier layer 106 to the reference layer 102. As a result, the electrons having an opposite spin will accumulate at the junction between the free layer 104 and barrier layer 106. This accumulation of spin polarized electrons causes a spin torque that causes the magnetization 110 of the free layer 104 to flip from a downward direction to an upward direction.

In order to assist the switching of the magnetization 110 of the free layer 104, the memory element 100 may include a spin polarization layer 130 formed above the free layer 104. The spin polarization layer can be separated from the free layer 104 by a coupling layer 132. The spin polarization layer 130 has a magnetic anisotropy that causes it to have a magnetization 134 with a primary component oriented in the in-plane direction (e.g. perpendicular to the magnetizations 110, 108 of the free and reference layers 104, 102. The magnetization 134, of the spin polarization layer 130 may either be fixed or can move in a precessional manner as shown in FIG. 100. The magnetization 134 of the spin polarization layer 130 causes a spin torque on the free layer 104 that assists in moving its magnetization away from its quiescent state perpendicular to the plane of the free layer 104. This allows the magnetization 110 of the free layer 104 to more easily flip using less energy when applying a write current to the memory element 100.

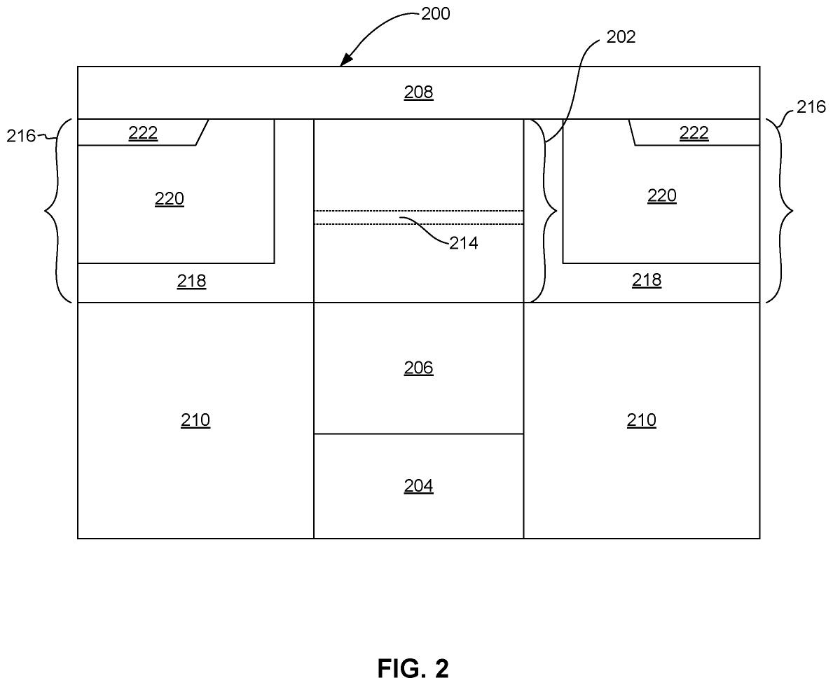

FIG. 2 shows a side, cross sectional view of a magnetic memory element 202, incorporated into a magnetic memory array 200, a small portion of which is shown in FIG. 2. Although only one memory element 202 is shown in FIG. 2, it should be appreciated that this is for purposes of illustration and that the memory array 200 can include many memory elements 202. The memory element 202 can be connected with circuitry such as CMOS circuitry 204, and connection between the memory element 202 and the circuitry 204 can be accomplished via a first electrode 206. The memory element 202 can also be connected with a second electrode 208 for further connection with memory array circuitry. Areas at either side of the circuitry 204 and first electrode 206 can be filled with a dielectric fill material 210 such as SiO₂.

The memory element 202 can have a structure such as the memory element 100 described above with reference to FIG. 1. Although this is by way of example, as the memory element 202 can have some other suitable structure. As shown in FIG. 2, the memory element 202 can include a thin barrier layer 214, which is preferably a material such as MgOx. In addition, a novel dielectric isolation layer structure 216, which will be described in greater detail herein below, is formed at either side of the memory element 202 in order to electrically isolate the memory element 202 to ensure that switching is applied across the memory element 202 as desired and not shunted at areas outside of the memory element 202.

Maintaining a desired crystal structure and thickness of the barrier layer 214 is important to maintaining good magnetic tunnel junction performance. However, it has been found that high temperature treatment processes necessary for the CMOS circuitry fabrication which are performed after formation of the magnetic memory element 202 can degrade the structure of the barrier layer 214 and, therefore, negatively affect memory element performance.

The nanofabrication of magnetic memory element pillars in magnetic memory arrays involves the use of back-end CMOS semiconductor circuitry fabrication technology. Part of this back-end-of-line CMOS processing requires a thermal treatment after the formation of the magnetic memory element pillars (e.g. 202). This thermal treatment can include treatment at temperatures of up to 400 degrees Celsius for an extended period of time.

Because this thermal annealing treatment is performed after the formation of the memory element pillars 202, the pillars and surrounding structure must be designed to withstand such thermal treatments. One challenge that arises as a result of the thermal annealing is the affect of such thermal treatment on the already formed barrier layer 214, especially with regard to the use of dielectric isolation layer structures at the side of the memory element. Materials such as silicon oxides (SiOx) and silicon nitrides (SiNx) are desirable materials for use in such isolation structure for electrically isolating pillar structures from one another, because they have good dielectric properties and good properties for chemical mechanical polishing (CMP), the use of which will be described in greater detail herein below. However, at such high temperatures Si from the SiOx or SiNx layers can diffuse into the barrier layer, greatly degrading the performance of the memory element by negatively affecting the quantum tunneling properties of the barrier layer 214 and also by creating shunting paths at the outer edges of the barrier layer 214 due to formation of conductive Si nanocrystal filaments in proximity of the barrier layer 214. This problem is further exacerbated by the fact that the milling process used to form the pillar structure forms a rough surface on the outer edge of the pillar structure. This rough edge forms nucleation points which encourage the formation of Si nanocrystals at the outer edge of the pillar structure. These nanocrystals can connect to each other and act as electrical shunts which lead to low device resistance and greatly reduced performance of the memory element. In addition, defects in the MgO barrier resulting from the presence of Si degrade the tunneling properties of the MgO barrier layer, substantially decreasing TMR performance.

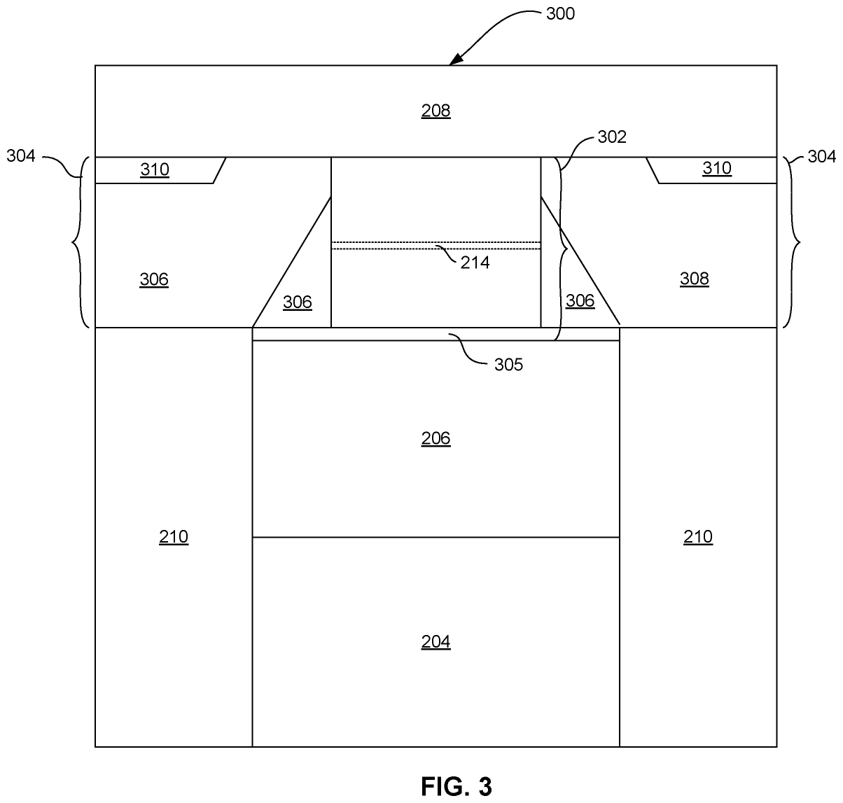

A novel structure as described generally with reference to FIGS. 2 and 3 solves this problem by mitigating the effects of having a SiOx or SiNx layer adjacent to the sides of the pillar structure. As shown in FIG. 2, an isolation structure 216 is formed as a multi-layer structure. The multi-layer isolation structure 216 includes a first layer 218 that is a bottom layer located adjacent to the memory element pillar structure 202. This first layer can be formed of the same material as the barrier layer 214 and is preferably in contact with the sides of the memory element pillar structure 202. In one exemplary embodiment, the barrier layer 214 and first layer 218 are both constructed of MgO.

The isolation structure 216 can further include one or more other types of dielectric layers formed over or beside the first layer 218, so that the first layer 218 separates these other layers from the pillar structure 202 and more importantly separates these other layers from the barrier layer 214. In the exemplary embodiment shown in FIG. 2, the isolation structure can include a second layer 220 formed over the first layer 218 and a third layer 222 formed over the second layer 220. In this exemplary embodiment, the second layer 220 can be silicon oxide (SiOx) and the third layer 222 can be formed of silicon nitride (SiNx). More preferably, the layer 220 is silicon dioxide (SiO₂). This structure provides advantages that will become more apparent below upon a discussion of a method for manufacturing a memory array. In this embodiment first layer 218 acts as a diffusion barrier effectively preventing Si from the SiOx or SiNx layers 220, 222 from migrating into and diffusing into the barrier layer 214. Advantageously, because the first layer 218 is formed of the same material as the barrier layer 216, it will have no negative impact on the properties of the barrier layer 214, even when subjected to prolonged high temperature treatment processes. In an optional, alternate embodiment, the second and third layers 220, 222 can be replaced with a single layer of, for example, SiNx or SiOx.

The first layer 218 can be constructed as a single layer or as a multi-layer structure and can be have a thickness of 1-5 nm. Preferably, the first layer 218 can be formed as a single layer of naturally oxidized or reactively oxidized Mg to form single MgO layer.

FIG. 3 shows a portion of a memory element array 300 according to an alternate embodiment of the invention. The memory element array 300 includes a magnetic memory element 302, which can include various layers similar to the memory element 100 of FIG. 1. The memory element 302 includes a barrier layer 214, which is preferably constructed of MgO. In addition, the memory element 302 can include a lower seed layer 305, which can be constructed of a material such as Tantalum (Ta), Ruthenium (Ru), Copper (Cu) and their respective Nitrides. As can be seen in FIG. 3, the seed layer 305 extends laterally outward from the rest of the memory element 302 and has an outer edge that can be aligned with an outer edge of the lower electrical contact 206. The lower electrical contact can be constructed of a material such as TaN, which is both electrically conductive and resistant to certain dry etching and ion milling processes for reasons that will become clearer herein below.

The memory element array 300 can be formed with an isolation structure 304 that includes first second and third layers 306, 308, 310. The first layer 306 is formed of a material that is the same as or similar to the material of the barrier layer 214 of the memory element pillar 202. For example, the barrier layer 214 can be formed of magnesium oxide and the first isolation layer 306 can be formed of magnesium oxide having an oxygen concentration that is within plus or minus 5 atomic percent of the magnesium oxide of the barrier layer 214. The first layer 306 has a tapered structure as shown in FIG. 3, wherein the layer 306 is narrower toward the top end of the memory element pillar 306 and wider toward its bottom end where it contacts the seed layer structure 305. As shown in FIG. 3, the bottom of the first layer 306 can be aligned with the outer edge of the memory element seed layer 305 while the narrower end near the top of the first layer 306 terminates before the top of the memory element 302 but extends above MgO layer 214. Therefore, the top of the first layer 306 terminates at a point that is between the barrier layer 214 and the top end of the memory element 302 so that it is not in contact with the top contact layer 208. The first isolation layer 306 is formed by a self-aligned process that will be described in greater detail herein below.

In the exemplary embodiment described with reference to FIG. 3, the second isolation layer 308 can be constructed of a dielectric material such as silicon oxide (SiOx) and the third isolation layer 310 can be constructed of a dielectric material such as silicon nitride (SiNx). The use of the second and third layers 308, 310 are advantageous for facilitating manufacture for reasons that will become clearer below. However, alternatively, the second and third layers 308, 310 can be formed as a single layer of a material such as SiOx or SiNx.

The tapered shape of the first layer 306 is optimal for both facilitating manufacturing such as by providing optimal properties for chemical mechanical polishing (CMP) and also effectively preventing Si diffusion into the barrier layer 214. MgOx is not an optimal material for chemical mechanical polishing (a process which will be needed to form a planar upper surface on the memory element pillar structure), while silicon oxide (SiOx) responds well to chemical mechanical polishing and provides good process control for chemical mechanical polishing. Because the first layer 306 does not extend to the top of the pillar structure 302, there will be no MgO at this region to be subject to chemical mechanical polishing. This advantageously leaves the SiOx layer 308 and SiNx layer 310 to withstand the chemical mechanical polishing. However, because the layer 306 is present in the region adjacent to the barrier layer structure 214 it can provide very effective protection against Si diffusion into the barrier layer. This advantageously allows greatly improved diffusion barrier protection while eliminating any disadvantage of having the MgOx being subject chemical mechanical polishing.

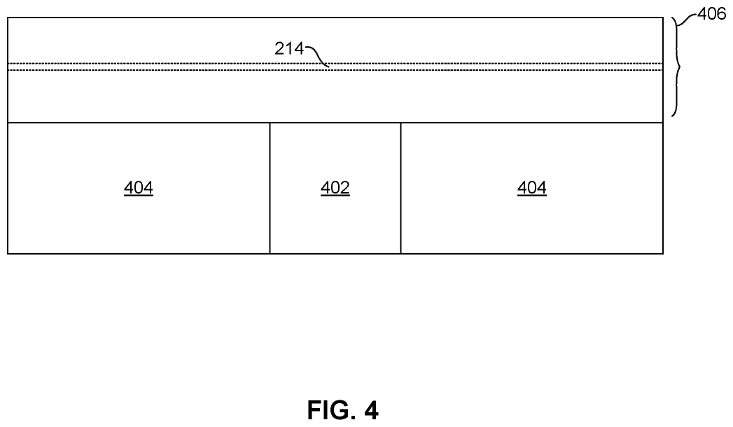

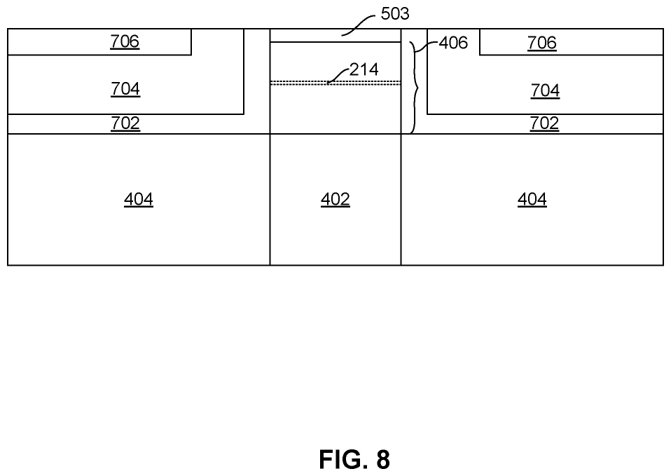

FIGS. 4-9 show a portion of a magnetic memory array in various intermediate stages of manufacture in order to illustrate a method of manufacturing a magnetic memory array according to an embodiment such as the embodiment shown with reference to FIG. 2. With particular reference to FIG. 4, a first, or lower, electrical contact 402 is formed. The electrical contact 402 can be surrounded by a dielectric material 404, such as silicon oxide or silicon nitride. The contact 402 can be constructed of an electrically conductive metal such as TaN. The electrical contact can be electrically connected with electrical circuitry (not shown) such as CMOS circuitry that can be located beneath the contact 402. The upper surface of the contact 402 and surrounding dielectric 404 can have a smooth coplanar surface that can be formed by chemical mechanical polishing (CMP). Magnetic memory element material 406 can be deposited over the coplanar surface of the contact 402 and surrounding dielectric material 404. Although shown as a single layer 406 in FIG. 4, it should be understood that the material 406 would actually include various layers necessary to construct a magnetic memory element pillar such the magnetic memory element pillar 100 of FIG. 1, or the memory elements 202, of FIG. 2.

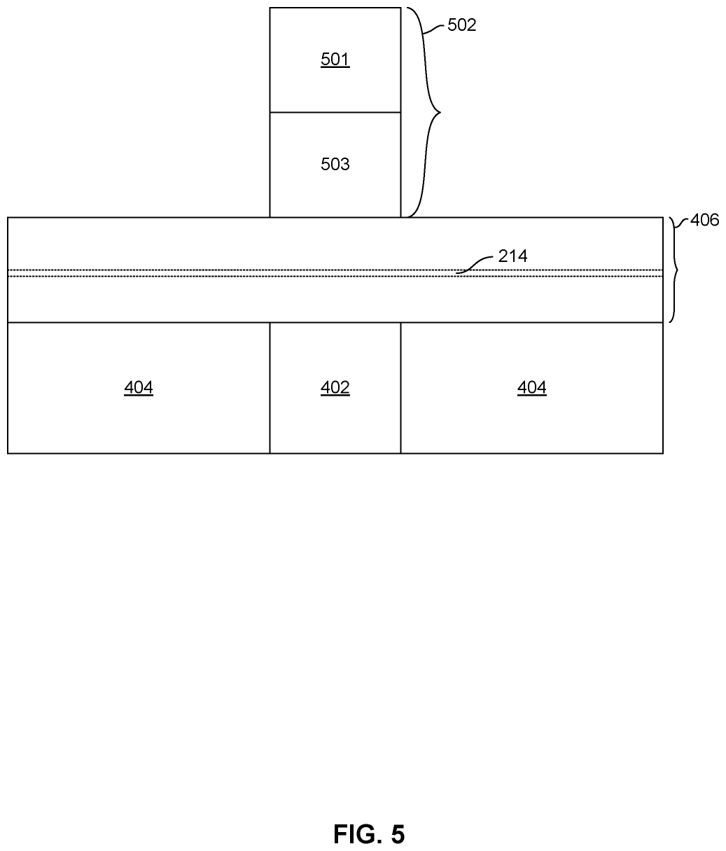

With reference now to FIG. 5, a mask structure 502 is formed over the magnetic memory element material 406. The mask may include various mask layers such as a photoresist mask, hard mask, adhesion layer etc., and as shown in FIG. 5 includes a photoresist mask structure 501 formed over a hard mask material 503 such as TaN. The mask 502 is configured to define a magnetic element pillar structure.

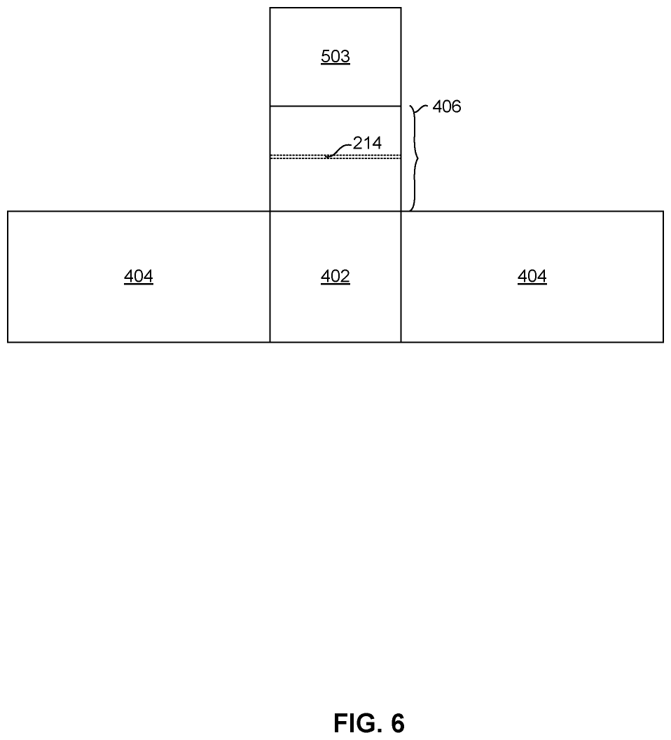

With the mask 502 in place, a material removal process is performed to remove portions of the magnetic element material 406 that are not protected by the mask structure 502, leaving a structure as shown in FIG. 6. The material removal process could be one of several available etching or milling processes but is preferably an ion beam etching process which has been shown to provide good performance in creating well defined magnetic element pillar structures. This material removal process used to define the pillar structure 406 can also remove the photoresist mask 501 (FIG. 5) leaving just the hard mask 503 over the pillar structure 406, as shown in FIG. 6.

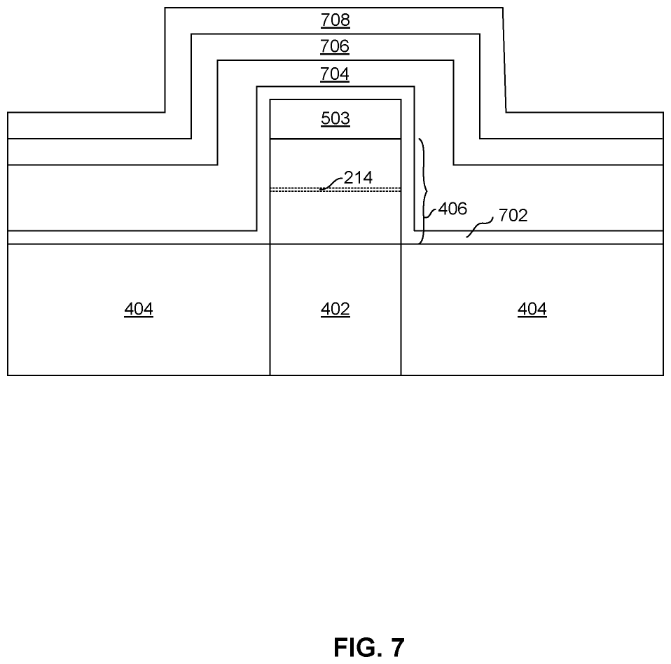

With reference now to FIG. 7, a series of dielectric isolation layers is deposited. A first layer 702 is deposited, preferably so as to be in direct contact with the magnetic element pillar structure 406. The first layer 702 is a dielectric layer that is the same as or similar to a material making up a barrier layer of the magnetic memory element structure 406 (such as the barrier layer 214 of FIGS. 2 and 3). Preferably, both the barrier layer (not shown) and the first layer 702 can be constructed of MgOx, with the first layer 702 having an oxygen content that is within plus or minus 5 atomic percent of that of the barrier layer (not shown).

The first layer 702 can be deposited by one of several deposition techniques so as to form an oxide, such as MgOx. Since the layer 702 is preferably MgOx so as to match with the barrier layer (not shown), the deposition of the first layer 702 will be described as a process for depositing MgOx. One way to deposit a MgOx layer 702 is by a plasma vapor deposition (PVD) process in a deposition chamber using a target containing both Mg and O (e.g. a MgO target). In this deposition process Radio Frequency (RF) sputtering can be used by sputtering MgO directly from the MgO target. Alternatively, the deposition of the layer 702 can be performed using DC magnetron sputtering or radio frequency (RF) sputtering and can be deposited as a series of layers or as a single layer. Preferably, however, the layer 702 is deposited as a series of layers of Magnesium (Mg) using a Plasma Vapor Deposition (PVD) process by sputtering from Mg target and is then reactively (ROx) or naturally (NOx) oxidized until a desired oxygen content is achieved to effectively match stochimetric MgO for layer 702. This process allows the layer 702 to be more easily deposited to a desired thickness (preferably 1-5 nm) and also advantageously allows good control of the oxidation process. Again, this process could be performed so as to deposit the layer 702 as multiple oxide layers rather than a single layer.

After the first layer 702 has been deposited, second, third and fourth layers 704, 706, 708 are successively deposited over the first layer 702. The second layer 704, deposited directly over the first layer 702, can be silicon oxide (SiOx). The third layer 706 can be deposited as a dielectric layer that is resistant to chemical mechanical polishing (CMP) so as to make a good CMP stop layer. For example, the third layer 706 is preferably SiNx, which provides good dielectric properties and also functions as a good CMP stop layer. The fourth layer 708 is preferably formed of SiOx, which provides good properties for subsequent chemical mechanical polishing (CMP) such as good control of CMP material removal rate. The second, third and forth layers 704, 706, 708 can all be deposited by various conformal deposition processes and are preferably deposited by plasma-enhanced chemical vapor deposition (PECVD).

After the layers 702, 704, 706, 708 have been deposited, a chemical mechanical polishing (CMP) can be performed to planarize the structure. The CMP process is performed until the third layer 706 is reached. The layer 706 is used as a CMP stop layer (as discussed) because of its good resistance to removal by CMP. The fourth layer 708, which was included to facilitate the CMP process can be removed by the CMP, leaving a structure such as that shown in FIG. 7.

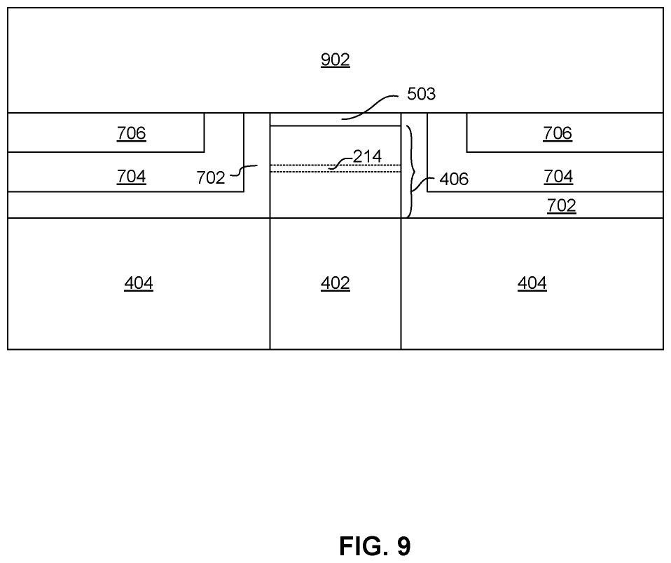

With reference to FIG. 9, after the chemical mechanical polishing process has been performed, an electrically conductive contact layer 902 is formed over the memory element pillar structure 406 and isolation layers 702, 704, 706. The electrically conductive contact layer 902 can be deposited by sputter deposition or electroplating and can be a material such as TaN.

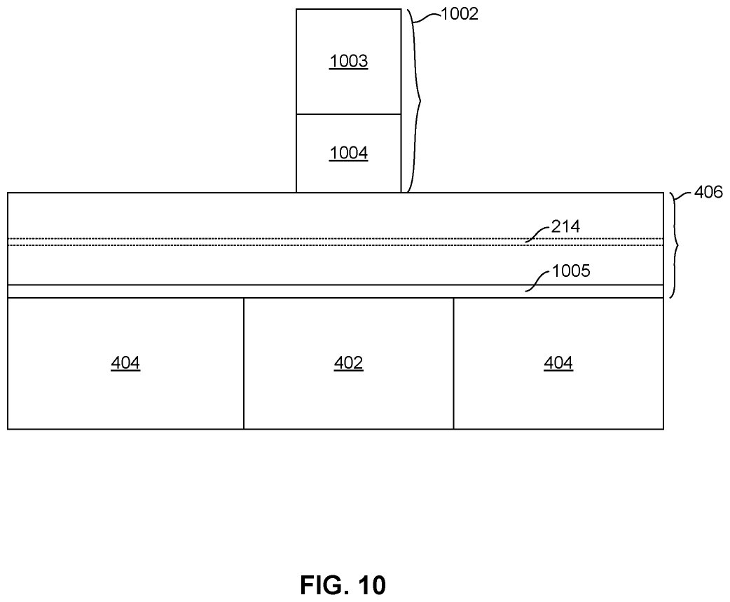

FIGS. 10-15 show a magnetic memory array in various intermediate stages of manufacture in order to illustrate a method of forming a magnetic memory array according to an alternate embodiment. With particular reference to FIG. 10, a first electrical contact 402 is formed. The first electrical contact can be surrounded at its side by a dielectric layer 404, such as silicon oxide or silicon nitride. Magnetic memory element material 406 is deposited over the first contact 402 and surrounding dielectric 404. As with the previously described embodiment, the magnetic memory element material 406 can include various material layers necessary to form a magnetic element pillar such as the memory element pillar 100 described with reference to FIG. 1. The memory element material may also include a seed layer 1005 deposited at the bottom of the memory element material 406. The seed layer 1005 can be a material such as Ta, Ru, Cu or their Nitrides respectively. A mask structure 1002 is formed over the memory element material 406. The mask structure 1002 can include a photoresist mask 1003 formed over a hard mask structure 1004 such as TaN or Diamond like Carbon (DLC) and is configured to define a diameter of a desired memory element pillar. In addition to the layers 1003, 1004, the mask structure 1002 can include other layers (not shown) such as adhesion layers, bottom antireflective coating layers, etc.

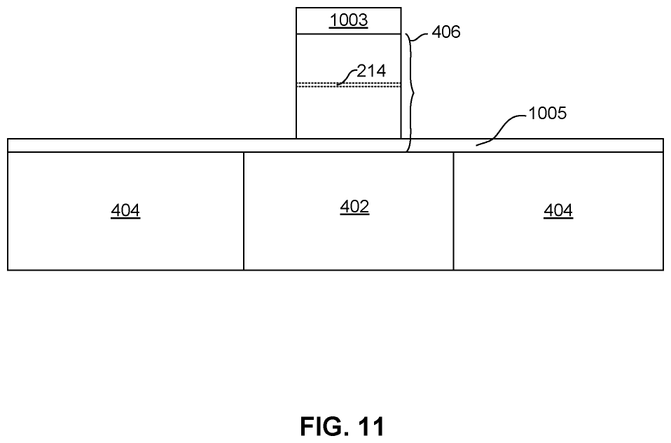

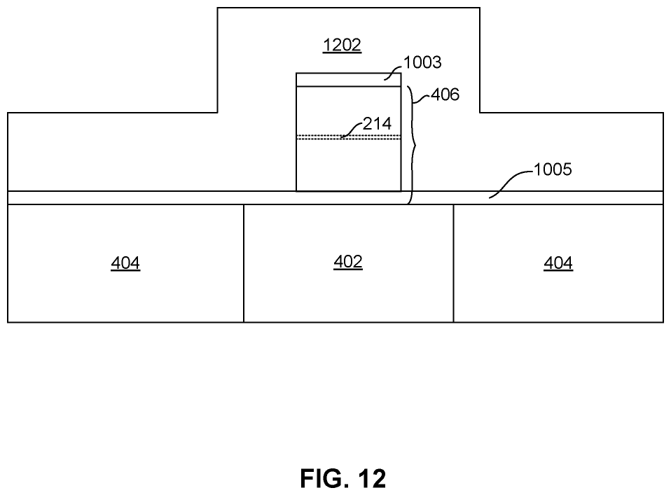

With reference to FIG. 11, a material removal process such as ion beam etching is performed to remove portions of the memory element material that are not protected by the mask structure 1002 in order to form a memory element pillar 406. This material removal process may remove the photoresist mask 1003 (FIG. 10) and may also consume some of the hard mask structure 1004, leaving the structure shown in FIG. 11. As shown in FIG. 12, the material removal process used to form the pillar structure 406 is terminated before removing the seed layer 1005. Also, not shown, the material removal process can be terminated earlier leaving part of the layer 406 thickness not etched as long as it is terminated after etching through MgO layer 214. This leaves the seed layer or seed layer with part of the MTJ structure 406 extending beyond the sides of the pillar structure 406 as shown. The seed layer 1005 can be constructed of a material such as Ta, Ru, or Cu.

With reference to FIG. 12, a first dielectric isolation layer 1202 is deposited over the layer 1005. The first dielectric isolation layer 1202 is a material that is the same as or similar to the barrier layer material 214 of the magnetic memory element layer 406. Preferably both the barrier layer 214 of the magnetic memory element 406 and the first dielectric layer 1202 are formed of MgO, and preferably both layers have about the same oxygen content as one another. In one possible embodiment, the first dielectric layer 1202 is deposited to a thickness that is about the same as the thickness of the magnetic memory element pillar 406.

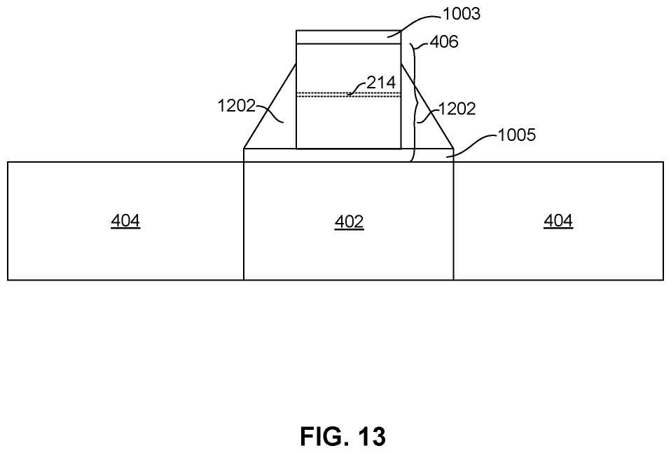

Then, an etching process is performed to etch back the first dielectric layer 1202. This etching process causes the first dielectric layer to form a tapered dielectric sidewall 1202 as shown in FIG. 13. The tapered dielectric sidewall is thinner at the top and thicker at the bottom, which provides advantageous that will become clearer herein below. This etching process also remove an outer portion of the seed layer 1005, leaving an outer edge of the seed layer 1005 that is self-aligned with the bottom portion of the remaining first dielectric isolation layer 1202. The etching process is also performed sufficiently that the top of the side tapered sidewall 1202 terminates at a location between the barrier layer 1402 and the top of the memory element pillar structure 406 such that it terminates short of the top of the memory element pillar structure 406.

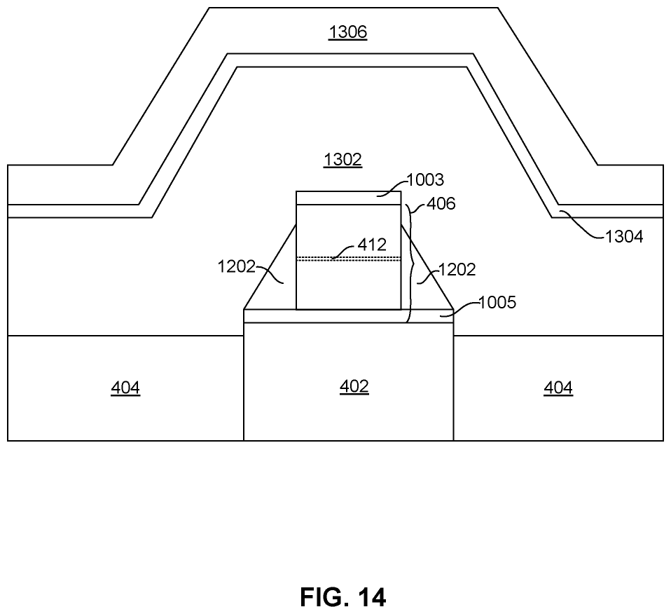

With reference to FIG. 14, second, third and fourth dielectric layers 1302, 1304, 1306 are sequentially deposited over the first dielectric layer 1202. The second dielectric layer 1304 is preferably silicon oxide (SiOx) and can be deposited directly over the first dielectric layer 1202. The third dielectric layer 1304 is preferably silicon nitride (SiNx) and can be deposited directly over the second dielectric layer 1302. Silicon nitride has good dielectric properties, but also has good properties for use as a stop layer for chemical mechanical polishing (i.e. it makes a good CMP stop), as it has good resistance to removal by CMP. The fourth layer 1306 can be another layer of silicon oxide (SiOx) and can be deposited directly onto the third layer 1304. The second, third and fourth dielectric layers are preferably deposited by physical electron beam vapor deposition, although they could be deposited by some other conformal deposition process as well. Optionally, the second and third layers 1304 could be deposited as a single layer, of for example, SiNx.

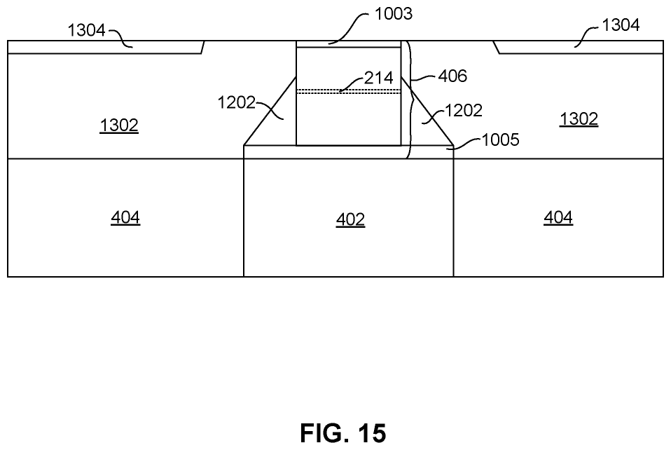

After the layers 1302, 1304, 1306 have been deposited, a chemical mechanical polishing process can be performed to planarize the structure, leaving a structure as shown in FIG. 15. As can be seen in FIG. 15, the chemical mechanical polishing (CMP) removes substantially all of the fourth dielectric layer 1306 and is terminated at the level of the third dielectric layer 1304, which as discussed above is a material such as SiNx that has properties to make it a good CMP stop layer. The above deposited fourth dielectric layer 1306, which is preferably SiOx, facilitates the CMP process until the CMP stop layer 1304 is reached, because it provides good control of CMP material removal rate.

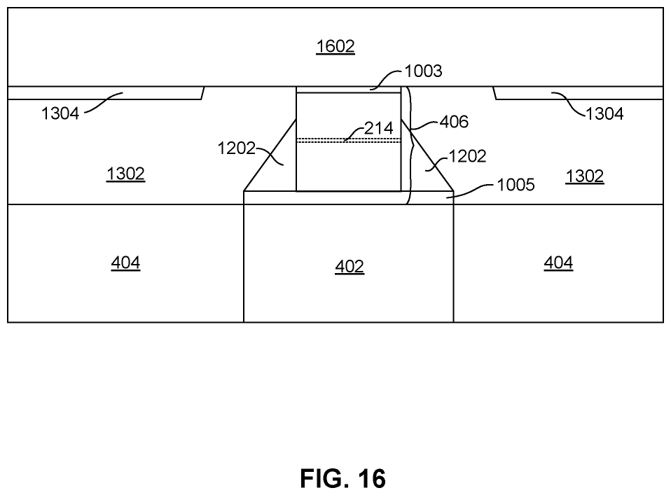

With reference to FIG. 16, after the CMP process has been performed to planarize the structure, an upper lead 1602 can be formed. The upper lead 1602 can be of various electrically conductive metals and is preferably Ta, TaN and Aluminium (Al) or combination of both.

While various embodiments have been described above, it should be understood that they have been presented by way of example only and not limitation. Other embodiments falling within the scope of the invention may also become apparent to those skilled in the art. Thus, the breadth and scope of the inventions should not be limited by any of the above-described exemplary embodiments but should be defined only in accordance with the following claims and their equivalents.

What is claimed is:

1. A magnetic memory device, comprising:
a magnetic memory element having a side and having a barrier layer;
a first isolation layer comprising a material similar to the barrier layer; and
a second isolation layer formed adjacent to the first barrier layer, such that the first barrier layer separates the magnetic memory element from the second isolation layer.

2. The magnetic memory device as in claim 1, wherein the barrier layer and the first isolation layer each comprise magnesium oxide.

3. The magnetic memory device as in claim 1, wherein the barrier layer is formed of a material comprising a set of elements, and the first isolation layer is formed of a material comprising the same set of elements as the barrier layer.

4. The magnetic memory device as in claim 1, wherein the second isolation layer comprises silicon oxide.

5. The magnetic memory device as in claim 1, wherein the barrier layer comprises magnesium oxide having an oxygen concentration, and the first isolation layer comprises magnesium oxide having an oxygen concentration that is the same as the oxygen concentration of the barrier layer within plus or minus 5 atomic percent.

6. The magnetic memory device as in claim 1, wherein the first isolation layer comprises multiple layers of magnesium oxide.

7. The magnetic memory device as in claim 1, wherein the barrier layer comprises magnesium oxide and the first isolation layer comprises a single layer of magnesium oxide having an oxygen concentration that is within plus or minus 5 atomic percent of an atomic oxygen concentration of the barrier layer.

8. The magnetic memory device as in claim 1, wherein the barrier layer and the first isolation layer each comprise magnesium oxide and the second isolation layer comprises silicon oxide, the magnetic memory device further comprising a third isolation layer formed over the second isolation layer.

9. The magnetic memory device as in claim 8, wherein the third isolation layer comprises silicon nitride.

10. The magnetic memory device as in claim 1, wherein the first isolation layer has a has a tapered shape.

11. The magnetic memory device as in claim 1, wherein the first isolation layer has a tapered shape and terminates at a location that is between the barrier layer and an end of the memory element.

12. The magnetic memory device as in claim 1, wherein a portion of the magnetic memory element extends laterally further than the rest of the magnetic memory element and the first isolation layer has a tapered shape that extends over the laterally extended portion of the memory element.

13. A method for manufacturing a magnetic memory device, comprising:
forming an electrically conductive contact;
forming a magnetic memory element pillar over the electrically conductive contact the magnetic memory element pillar having a barrier layer formed therein;
depositing a first isolation layer over the magnetic memory element pillar, the first isolation layer being a material that is similar to the barrier layer; and
depositing a second isolation layer over the first isolation layer.

14. The method as in claim 13, further comprising, after depositing the second isolation layer, depositing a third isolation layer, the third isolation layer being a material suitable for use as a chemical mechanical polishing stop layer.

15. The method as in claim 13 further comprising:
after depositing the second isolation layer, depositing a third isolation layer over the second isolation layer and depositing a fourth layer over the third isolation layer, the third isolation layer being a material that is suitable for use as a chemical mechanical polishing stop and the fourth layer being a material that facilitates good chemical mechanical polishing properties; and
after depositing the fourth layer, performing a chemical mechanical polishing until the third layer has been reached.

16. The method as in claim 15, wherein the first layer comprises magnesium oxide, the second layer comprises silicon oxide, the third layer comprises silicon nitride and the fourth layer comprises silicon oxide.

17. The method as in claim 16, wherein the first layer is magnesium oxide deposited by sputter deposition using a Mg target followed by an oxidation step.

18. The method as in claim 17, wherein the oxidation step is a natural oxidation step.

19. The method as in claim 17, wherein the oxidation is a reactive oxidation step.

20. The method as in claim 16, wherein the first layer is deposited by radio frequency sputter deposition using a MgO target.

21. The method as in claim 13, wherein the forming of the magnetic element pillar further comprises:
depositing a magnetic memory element material including a barrier layer;
forming a mask structure over the magnetic memory element material;
performing a material removal process to remove a portion of the magnetic memory element material that is not protected by the mask structure, the material removal process being performed sufficiently to remove a portion of the electrical contact that is not protected by the memory element material and the mask structure;
the method further comprising;
after depositing the first isolation layer, and before depositing the second isolation layer, performing a second material removal process to cause the first isolation layer to form a tapered sidewall structure on a side of the magnetic memory element pillar.
